(19) United States
(12) Patent Application Publication
(10) Pub. No.: US 2019/0337288 A1
(43) Pub. Date: Nov. 7, 2019

(54) THERMOELECTRIC CONVERSION DEVICE AND PRINTER

(71) Applicant: Panasonic Intellectual Property Management Co., Ltd., Osaka (JP)

(72) Inventor: TAKAFUMI SHINGAI, Kumamoto (JP)

(21) Appl. No.: 16/462,491

(22) PCT Filed: Nov. 21, 2017
(86) PCT No.: PCT/JP2017/041745

§ 371 Date: May 20, 2019

(30) Foreign Application Priority Data
Dec. 7, 2016 (JP) 2016-237317

(51) Int. Cl. B41F 23/04; F25B 21/02; H01L 35/30

(52) U.S. Cl. CPC B41F 23/0476; F25B 2321/0212; H01L 35/30; F25B 21/02

(57) ABSTRACT

A thermoelectric conversion unit includes a cylindrical body made of a thermally conductive material, a plurality of thermoelectric converters disposed on an inner peripheral surface of the cylindrical body, a heat transfer member, and a heat pipe installed in the heat transfer member. Each of the plurality of thermoelectric converters has an operating surface facing the inner peripheral surface and an inversely operating surface positioned at a side opposite to the operating surface. The heat transfer member is disposed on the inversely operating surface. Heat transfers between each of the plurality of thermoelectric converters and the heat transfer member via the inversely operating surface. The plurality of thermoelectric converters are divided into a plurality of sets of thermoelectric converters, and the heat transfer member and the heat pipe are provided for each of the plurality of sets of the thermoelectric converters. The heat pipe is disposed, in the heat transfer member, along positions of respective thermoelectric converters included in each of the plurality of sets of the thermoelectric converters.

### TECHNICAL FIELD

The present disclosure relates to a thermoelectric conversion device and a printer having the thermoelectric conversion device.

### BACKGROUND

The thermoelectric conversion device for cooling or heating an object is mounted in various apparatuses. The thermoelectric conversion device is equipped with, for example, a thermoelectric converter in which a thermoelectric conversion element such as a Peltier element is integrated. In this case, a configuration for exhausting heat from a surface positioned at a side opposite to an operating surface of the thermoelectric converter is required.

In Patent Literature 1, an electronically cooled cooling unit using an electronic thermo-module is described. In this configuration, heat transferred from the electronic thermo-module to a heat receiving block is exhausted to the atmosphere via a heat pipe.

### CITATION LIST

### Patent Literature

PTL 1: Unexamined Japanese Patent Publication No. H9-113058

### SUMMARY

A first aspect of the present disclosure relates to a thermoelectric conversion device. The thermoelectric conversion device according to the first aspect includes a cylindrical body made of a thermally conductive material, a plurality of thermoelectric converters disposed on an inner peripheral surface of the cylindrical body, a heat transfer member, and a heat pipe installed in the heat transfer member. Each of the plurality of thermoelectric converters has an operating surface facing the inner peripheral surface and an inversely operating surface positioned at a side opposite to the operating surface. The heat transfer member is disposed on the inversely operating surface. Heat transfers between each of the plurality of thermoelectric converters and the heat transfer member via the inversely operating surface. The plurality of thermoelectric converters are divided into a plurality of sets of thermoelectric converters, and the heat transfer member and the heat pipe are provided for each of the plurality of sets of the thermoelectric converters. The heat pipe is disposed, in the heat transfer member, along positions of respective thermoelectric converters included in each of the plurality of sets of the thermoelectric converters.

According to the thermoelectric conversion device of this aspect, the heat pipe serves to maintain the temperature of the heat transfer member substantially equivalent at positions where the thermoelectric converters of the set are disposed. Therefore, the temperatures of the inversely operating surfaces respectively positioned at a side opposite to the operating surfaces can be maintained substantially uniform among the thermoelectric converters. This makes it possible to keep the operating surface more stably and at a substantially uniform temperature among the thermoelectric converters.

A second aspect of the present disclosure relates to a printer. The printer according to the second aspect includes the thermoelectric conversion device according to the first aspect, a printing section configured to perform printing on a sheet-shaped material to be printed, and a conveying section configured to convey the sheet-shaped material from the printing section to the thermoelectric conversion device.

According to the printer according to this aspect, since the thermoelectric conversion device according to the first aspect is provided, the temperature of the sheet-shaped material that is an object can be efficiently and stably controlled.

As described above, according to the present disclosure, a thermoelectric conversion device capable of maintaining temperatures of inversely operating surfaces respectively positioned at a side opposite to the operating surfaces of the thermoelectric converters substantially uniform when a plurality of thermoelectric converters are used, and a printer using the same can be provided.

Effects or meanings of the present disclosure will be further clarified in the following description of an exemplary embodiment. However, the exemplary embodiment described below is merely an example of implementing the present disclosure, and the present disclosure is not at all limited to the examples described in the following exemplary embodiment.

### BRIEF DESCRIPTION OF DRAWINGS

FIG. 1 is a view schematically illustrating a configuration of a printer according to an exemplary embodiment.

FIG. 2A is a plan view schematically illustrating a configuration of a thermoelectric conversion unit according to the exemplary embodiment.

FIG. 2B is a plan view schematically illustrating a conveying process for printing paper in the thermoelectric conversion unit according to the exemplary embodiment.

FIG. 2C is a plan view schematically illustrating a conveying process for printing paper in the thermoelectric conversion unit according to the exemplary embodiment.

FIG. 3A is a view schematically showing a state of the thermoelectric conversion unit according to the exemplary embodiment as seen from a cooling air inlet port side.

FIG. 3B is an exploded perspective view schematically illustrating a configuration of a structure to be mounted on the thermoelectric conversion unit according to the exemplary embodiment.

FIG. 4 is a view schematically illustrating a configuration of a heat pipe according to the exemplary embodiment.

FIG. 5A is an exploded perspective view schematically illustrating a configuration of a thermoelectric converter according to the exemplary embodiment.

FIG. 5B is a perspective view schematically illustrating a configuration of the thermoelectric converter according to the exemplary embodiment in a state of being completely assembled.

FIG. 6A is a view schematically illustrating a connecting state of feeder cables in the thermoelectric conversion unit according to the exemplary embodiment.

FIG. 6B is a graph schematically illustrating a cooling capacity when the thermoelectric conversion unit according to a comparative example is used.

FIG. 7A is a view schematically illustrating a temperature distribution in a heatsink when the thermoelectric conversion unit according to the comparative example is used.

FIG. 7B is a graph illustrating a relationship between a temperature of the heatsink at positions where thermoelectric converters are disposed, and a temperature of cooling surfaces (operating surfaces) of the respective thermoelectric converters when the thermoelectric conversion unit according to the comparative example is used.

FIG. 8A is a view schematically illustrating a temperature distribution in a heatsink when the thermoelectric conversion unit according to the exemplary embodiment is used.

FIG. 8B is a graph illustrating a relationship between temperatures of the heatsink at positions where thermoelectric converters are disposed, and a temperature of cooling surfaces (operating surfaces) of the respective thermoelectric converters when the thermoelectric conversion unit according to the exemplary embodiment is used.

FIG. 9A is a view schematically illustrating a connecting state of feeder cables in a thermoelectric conversion unit according to a first modified example.

FIG. 9B is a view schematically illustrating the connecting state of the feeder cables in the thermoelectric conversion unit according to the first modified example.

FIG. 10A is a view schematically illustrating a state in which a printing paper having a narrow width is conveyed to the thermoelectric conversion unit according to the first modified example.

FIG. 10B is a graph schematically illustrating a cooling capacity when the thermoelectric conversion unit according to the first modified example is used.

FIG. 11A is a view schematically illustrating a state in which two heat pipes are mounted according to the first modified example.

FIG. 11B is a view schematically illustrating a state in which the two heat pipes are mounted according to the first modified example.

FIG. 12 is a view schematically illustrating a state in which heat pipes are mounted according to a second modified example.

### DESCRIPTION OF EMBODIMENT

Prior to description of an exemplary embodiment of the present disclosure, problems found in conventional techniques will briefly be described. The thermoelectric conversion device may be configured to cool an object by a plurality of thermoelectric converters. In this configuration, it is preferable that heat dissipating surfaces positioned at a side opposite to cooling surfaces of the plurality of thermoelectric converters are maintained substantially at the same temperature when the object is cooled uniformly. When the heat dissipating surfaces of the plurality of thermoelectric converters are cooled by a cooling medium such as cooling air, a temperature of the cooling medium rises as the cooling medium moves across the heat dissipating surfaces of the plurality of thermoelectric converters. Hence, the temperatures of the heat dissipating surfaces of the thermoelectric converters located on the downstream side of a flow of the cooling medium are higher than the temperatures of the thermoelectric converters located on the upstream side of the flow of the cooling medium.

In view of such a problems, the present disclosure provides a thermoelectric conversion device capable of maintaining temperatures of inversely operating surfaces (heat dissipating surfaces) positioned at a side opposite to operating surfaces (cooling surfaces) of thermoelectric converters substantially uniformly when a plurality of the thermoelectric converters are used, and a printer using the same.

An exemplary embodiment of the present disclosure will be described below with reference to the accompanying drawings. For convenience, X, Y and Z-axes perpendicular to one another are added to respective drawings.

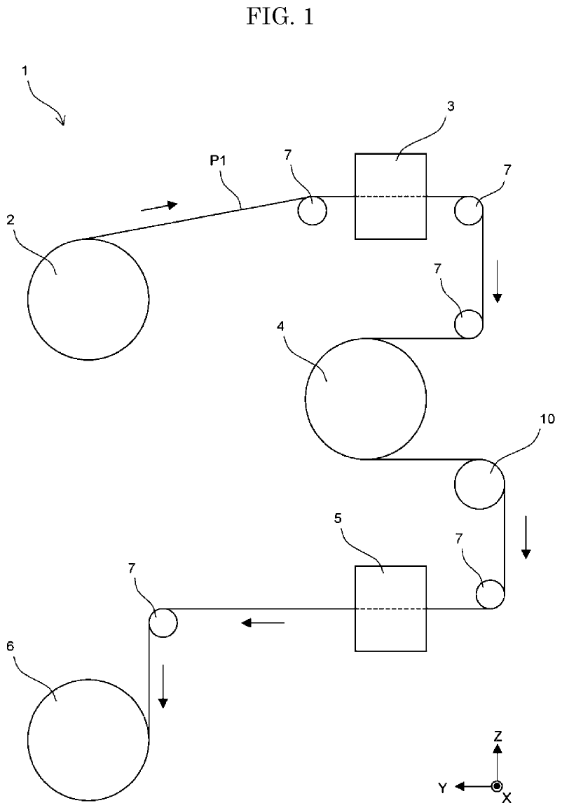

FIG. 1 is a view schematically illustrating a configuration of printer 1. FIG. 1 illustrates a configuration example of industrial printer 1. Printer 1 is not limited to the industrial printer, and may be a consumer printer.

Printer 1 includes front side printing unit 3, dryer 4, and back side printing unit 5 which are disposed along a conveyance passage. On the conveyance passage, printing paper P1 having a belt shape and drawn from roll paper 2 is conveyed. Front side printing unit 3 performs printing on a front side of printing paper P1. Dryer 4 heats and dries ink that is transferred from front side printing unit 3 to printing paper P1. Back side printing unit 5 performs printing on a back side of printing paper P1. Printed printing paper P1 is taken up by winding unit 6. Printing paper P1 is guided by rollers 7 to each part.

It should be noted that the object to be printed does not necessarily have to be paper, and may be other sheet-shaped material to be printed such as cloth. As described later, printing paper P2 having a smaller width in an X-axis direction than that of printing paper P1 may also be supplied to printer 1.

Furthermore, printer 1 includes thermoelectric conversion unit 10 between dryer 4 and back side printing unit 5. Thermoelectric conversion unit 10 cools printing paper P1 heated by dryer 4 to a temperature suitable for applying ink in back-side printing. Thermoelectric conversion unit 10 has a cylindrical shape. Thermoelectric conversion unit 10 rotates about an axis parallel to the X axis with printing paper P1 in contact with an outer peripheral surface. Printing paper P1 is cooled by contacting the outer peripheral surface of thermoelectric conversion unit 10.

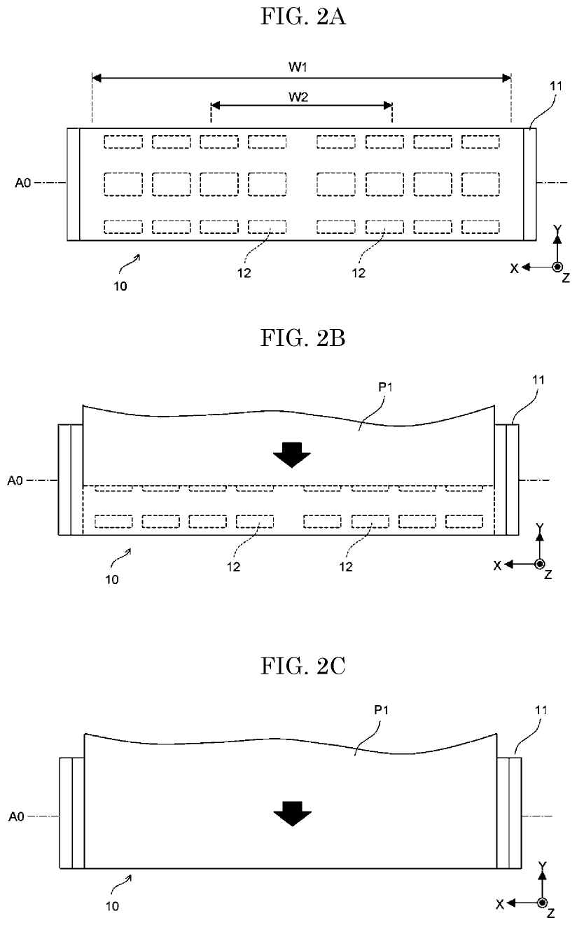

FIG. 2A is a plan view schematically illustrating a configuration of thermoelectric conversion unit 10. For convenience, in FIG. 2A, the configuration of a mechanical portion for rotating cylindrical body 11 about an axis parallel to the X-axis is omitted.

Thermoelectric conversion unit 10 includes cylindrical body 11 and a plurality of thermoelectric converters 12. Cylindrical body 11 has a cylindrical shape and includes openings respectively at an X-axis positive side and an X-axis negative side. Cylindrical body 11 is made of a material having excellent thermal conductive property such as copper, aluminum, or iron. A plurality of thermoelectric converters 12 are installed on an inner peripheral surface of cylindrical body 11.

Thermoelectric converters 12 are arranged along a periphery of cylindrical body 11 and disposed dispersedly along an axis (X-axis) of cylindrical body 11. In the specification of the present exemplary embodiment, the term “along an axis of cylindrical body 11” indicates along a direction parallel to a central axis (central axis of rotation) of cylindrical body 11 having a cylindrical shape, and the term, “along a periphery of cylindrical body 11” indicates along a circumference about the central axis of cylindrical body 11. In the present exemplary embodiment, thermoelectric converters 12 are arranged in line along the X-axis. FIG. 2A illustrates a configuration in which eight thermoelectric converters 12 are arranged along the X-axis. However, the number of thermoelectric converters 12 arranged along the X-axis is not limited thereto.

In the present exemplary embodiment, sets of thermoelectric converters 12 in each of which a plurality of thermoelectric converters are arranged along the X-axis are equally disposed along a periphery of cylindrical body 11. The number of sets of thermoelectric converters 12 arranged along a periphery of cylindrical body 11 is, for example, six, but is not limited thereto. The sets of thermoelectric converters 12, each of which is aligned along the X-axis, do not necessarily have to be disposed all around the inner peripheral surface of cylindrical body 11. Furthermore, the sets of thermoelectric converters 12, each of which is aligned along the X-axis, do not have to be arranged equidistantly along a periphery of cylindrical body 11.

Individual thermoelectric converters 12 have the same configuration and function as one another. Thermoelectric converters 12 cool the inner peripheral surface of cylindrical body 11 by being applied with a voltage. Therefore, when printing paper P1 contacts the outer peripheral surface of cylindrical body 11, heat of printing paper P1 is transferred from the outer peripheral surface to the inner peripheral surface of cylindrical body 11, and further to thermoelectric converters 12. Accordingly, printing paper P1 is cooled.

It should be noted that, in FIG. 2A, W1 indicates a width of contact of printing paper P1 with cylindrical body 11 when printing paper P1 is supplied to thermoelectric conversion unit 10, and W2 indicates a width of contact of printing paper P2 with cylindrical body 11 when printing paper P2 is supplied to thermoelectric conversion unit 10. Printing Paper P2 is narrower than printing paper P1.

FIGS. 2B and 2C are plan views schematically illustrating a conveying process of printing paper P1 in thermoelectric conversion unit 10. For convenience, FIG. 2B illustrates a state in which a Y-axis negative side of printing paper P1 is seen through.

Printing paper P1 is wound around the outer peripheral surface of cylindrical body 11 from a Y-axis positive side, and is carried in a Z-axis negative direction. In the conveying process, cylindrical body 11 rotates about an axis parallel to the X-axis with printing paper P1 being carried. Accordingly, the outer peripheral surface of cylindrical body 11 contacts with printing paper P1 in sequence. Printing paper P1 is cooled by thermoelectric converters 12 while being wound around the outer peripheral surface of cylindrical body 11. During this operation, by changing a conveying method of printing paper P1 so that the direction of conveyance of printing paper P1 is changed from Z-axis negative direction to Y-axis positive direction, cooling efficiency by thermoelectric converters 12 is enhanced because printing paper P1 wound around the outer peripheral surface of cylindrical body 11 for a longer distance.

It should be noted that the heat transferred from printing paper P1 to thermoelectric converters 12 is exhausted by cooling air flowing into an interior of cylindrical body 11. Cooling air is supplied into the interior of cylindrical body 11 by a blower, not illustrated. Cooling air flows from an opening (inlet port) at X-axis positive side of cylindrical body 11, and flows out from an opening (outlet port) at X-axis negative side of cylindrical body 11.

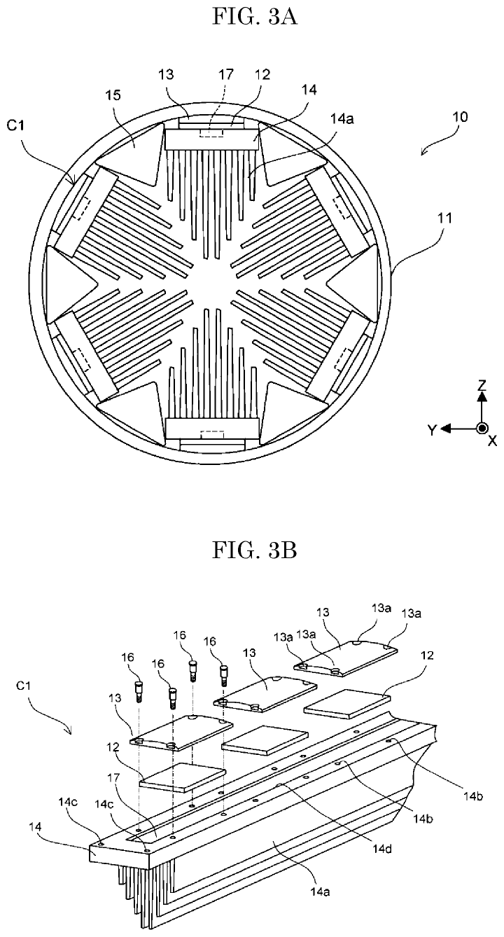

FIG. 3A is a view schematically illustrating thermoelectric conversion unit 10 as seen from a cooling air inlet port side. FIG. 3B is an exploded perspective view schematically illustrating a configuration of structure C1 to be mounted on thermoelectric conversion unit 10.

As illustrated in FIG. 3A, six structures C1 are uniformly mounted on the inner peripheral surface of cylindrical body 11. In addition, spacers 15 are disposed to fill spaces between one structure C1 and adjacent structures C1. In this configuration, a larger amount of cooling air may be directed toward heatsink 14.

As illustrated in FIG. 3B, structure C1 includes thermoelectric converters 12, presser plates 13, and heatsink 14. Heatsink 14 is a heat transfer member for transferring heat from an inversely operating surface (lower surface) positioned at a side opposite to an operating surface (upper surface) of thermoelectric converters 12.

Upper surfaces of presser plates 13 curve in conformity with the inner peripheral surface of cylindrical body 11, and have an arcuate shaped cross section. Presser plates 13 are fixed to heatsink 14 with screws 16 with thermoelectric converters 12 disposed between an upper surface of heatsink 14 and lower surfaces of presser plates 13. Presser plates 13 have holes 13a for allowing insertion of screws 16, and heatsink 14 has screw holes 14b for allowing screws 16 to be screwed in. Screws 16 are screwed into screw holes 14b through holes 13a. In this manner, thermoelectric converters 12 are mounted on the upper surface of heatsink 14.

It should be noted that only three thermoelectric converters 12 are illustrated in FIG. 3B because a portion near a front end of heatsink 14 is illustrated. Heatsink 14 has a shape extending further rearward. Eight thermoelectric converters 12 in total are mounted on the upper surface of heatsink 14 in the similar configuration as illustrated in FIG. 3B.

Heatsink 14 and presser plates 13 are made of a material having excellent thermal conductive property such as copper, aluminum, and the like. Presser plates 13 are sheet-shaped members. Heatsink 14 is a plate-shaped member having a predetermined thickness, and has a rectangular shape. The lower surface of heatsink 14 is provided with a plurality of plate-shaped fins 14a in parallel to each other. Fins 14a are made of a material excellent in thermal conductivity. In addition, heatsink 14 is provided with screw holes 14c penetrating from the top to the bottom at a front end and a rear end.

As illustrated in FIG. 3A, screws (not illustrated) are inserted into through holes (not illustrated) formed in cylindrical body 11 from an outer peripheral surface side to an inner peripheral surface side. And the screws are anchored in screw holes 14c in heatsink 14 in a state in which six structures C1 are arranged on an inner peripheral surface of cylindrical body 11. In this manner, as illustrated in FIG. 3A, six structures C1 are fixed to the inner peripheral surface of cylindrical body 11 evenly along the periphery of the cylindrical body 11.

Cooling air flowed into cylindrical body 11 passes through gaps between fins 14a and discharged from cylindrical body 11. Accordingly, heat transferring from thermoelectric converters 12 to fins 14a is removed. Accordingly, accumulation of heat on heat dissipating surfaces of thermoelectric converters 12 is suppressed, and cooling effect in thermoelectric converters 12 is maintained.

Furthermore, in the present exemplary embodiment, heat pipe 17 is provided on heatsink 14. As illustrated in FIG. 3B, the upper surface of heatsink 14 is provided with recess 14d extending in a longitudinal direction of heatsink 14. In recess 14d, heat pipe 17 is fitted. Heat pipe 17 is fitted into recess 14d so as to extend, in the longitudinal direction, from a portion near one of ends of heatsink 14 to a portion near the other end of heatsink 14. In other words, heat pipe 17 extends so as to overlap the positions of all eight thermoelectric converters 12, which are mounted on the upper surface of heatsink 14. In this manner, heatsink 14 includes recess 14d on a surface facing thermoelectric converters 12, and heat pipe 17 is fitted into recess 14d. Therefore, an effect of maintaining the temperature of the heat dissipating surfaces of the plurality of (eight) thermoelectric converters 12 substantially uniformly is enhanced and simultaneously, heatsink 14 having a compact size is achieved.

In this state, as described above, thermoelectric converters 12 and presser plates 13 are mounted on the upper surface of heatsink 14. Accordingly, heat pipe 17 is mounted on heatsink 14 in a state in which an upper surface of heat pipe 17 fitted into recess 14d is covered with thermoelectric converters 12. In this manner, the effect of maintaining the temperature of heat dissipating surfaces of the plurality of thermoelectric converters 12 substantially uniformly is efficiently enhanced by at least part of heat pipe 17 positioned in a space formed by recess 14d of heatsink 14 and thermoelectric converters 12. The heat dissipating surfaces are positioned at a side opposite to cooling surfaces (operating surfaces) of the plurality of thermoelectric converters 12. Furthermore, in a state in which the plurality of thermoelectric converters 12 are mounted, lower surfaces (heat dissipating surfaces) of thermoelectric converters 12 are each in contact with the upper surface of heat pipe 17. Therefore, the effect of maintaining the temperature of heat dissipating surfaces of the plurality of thermoelectric converters 12 substantially uniformly is enhanced further efficiently. Heat pipe 17 are mounted on all of six heatsinks 14 illustrated in FIG. 3A in the same manner.

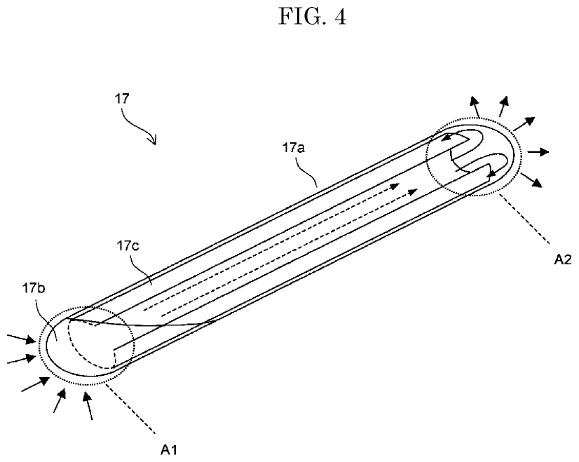

FIG. 4 is a view schematically illustrating a configuration of heat pipe 17. For convenience, in FIG. 4, the interior of heat pipe 17 is seen through, and wick (a core having a capillary structure) 17c is cut to have a slit along a longitudinal direction to make an inside of wick 17c disposed inside heat pipe 17 visible. Here, a heat pipe having a wick system is used as heat pipe 17.

Heat pipe 17 includes case 17a, operating fluid 17b, and wick 17c. Operating fluid 17b is sealed in case 17a. Wick 17c is disposed inside case 17a so as to extend along an inner wall of case 17a. In heat pipe 17, heat in high temperature portion A1 transfers to low temperature portion A2.

First of all, in an inner wall of high temperature portion A1, operating fluid 17b absorbs heat and evaporates. Next, vapor of operating fluid 17b passes through a void in wick 17c and move to low temperature portion A2. The vapor of operating fluid 17b is then cooled by low temperature portion A2, clumps together, and returns to a liquid. Operating fluid 17b returned to a liquid is absorbed by wick 17c, which is a core of capillary structure disposed along an inner wall of case 17a. Then, operating fluid 17b runs along wick 17c and returns back to high temperature portion A1. In this manner, heat transfers from high temperature portion A1 to low temperature portion A2 by circulation of operating fluid 17b in heat pipe 17.

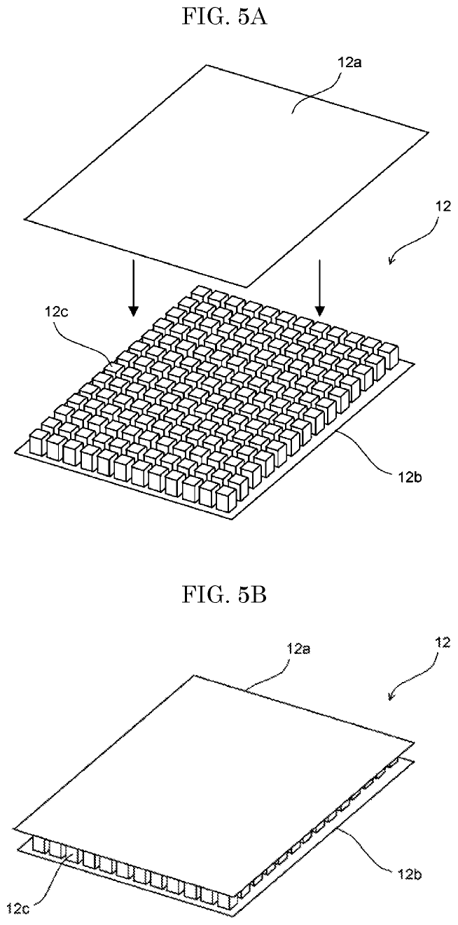

FIG. 5A is an exploded perspective view schematically illustrating a configuration of thermoelectric converter 12, and FIG. 5B is a perspective view schematically illustrating a configuration of thermoelectric converter 12 in a state of being completely assembled.

As illustrated in FIG. 5A, thermoelectric converter 12 includes first substrate 12a, second substrate 12b, and thermoelectric conversion elements 12c.

First substrate 12a and second substrate 12b have a substantially rectangular shape in plan view, and are formed of metallic material having a high thermal conductivity. As illustrated in FIG. 5A, first substrate 12a is overlapped on upper surfaces of thermoelectric conversion elements 12c in a state in which thermoelectric conversion elements 12c are disposed on an upper surface of second substrate 12b. Thermoelectric conversion elements 12c are arranged in an X-axis direction and in a Y-axis direction at constant pitches. Thermoelectric conversion elements 12c are elements for transferring heat based on an applied voltage and cooling such as Peltier elements.

It should be noted that a lower surface of first substrate 12a and an upper surface of second substrate 12b are respectively provided with connection electrodes (not illustrated). The connection electrodes are joined to upper electrodes and lower electrodes on thermoelectric conversion elements 12c.

Voltage is applied to thermoelectric conversion elements 12c via these connection electrodes. The connection electrode formed on first substrate 12a and the connection electrode formed on second substrate 12b are set such that a voltage is applied to all thermoelectric conversion elements 12c uniformly when a voltage is applied from a terminal not illustrated to thermoelectric converter 12 assembled as illustrated in FIG. 5B.

For assembly, thermoelectric conversion elements 12c are disposed as illustrated in FIG. 5A in a state in which solder is applied to the connection electrode on the upper surface of second substrate 12b. In addition, first substrate 12a is placed on the upper surface of thermoelectric conversion elements 12c as illustrated in FIG. 5B in a state in which solder is applied to the connection electrode on the lower surface of first substrate 12a. In this state, a reflow process is performed for welding solder. Accordingly, the respective connection electrodes are joined to thermoelectric conversion elements 12c, so that first substrate 12a and second substrate 12b are secured. In this manner, thermoelectric converter 12 is constructed as illustrated in FIG. 5B. When a voltage is applied to thermoelectric converter 12, heat of a cooling surface (upper surface of first substrate 12a) of thermoelectric converter 12 transfers to a heat dissipating surface (lower surface of second substrate 12b) of thermoelectric converter 12.

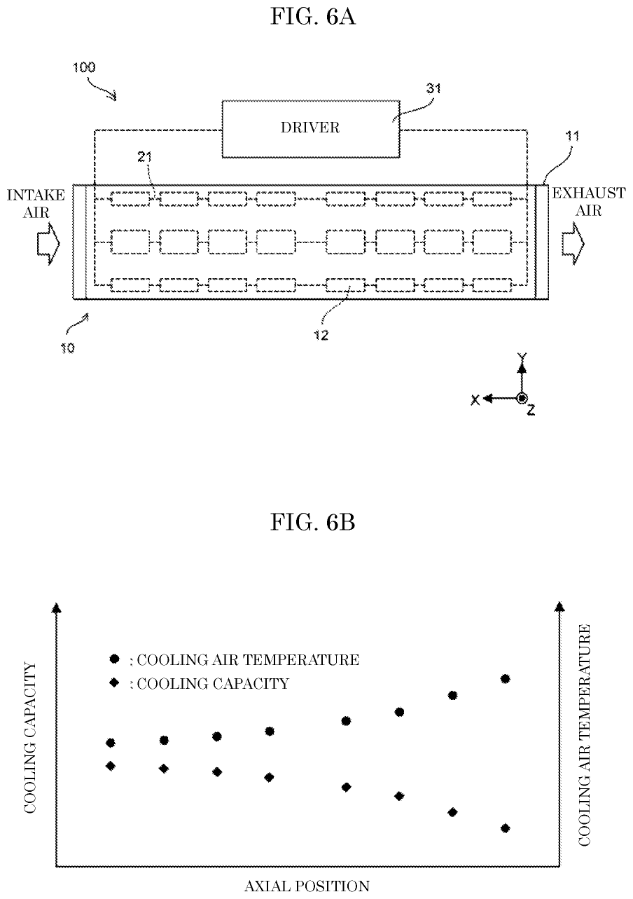

FIG. 6A is a view schematically illustrating a connecting state of feeder cables 21 in thermoelectric conversion unit 10. It should be noted that driver 31 and thermoelectric conversion unit 10 (including feeder cables 21) illustrated in FIG. 6A constitute thermoelectric conversion device 100.

As illustrated in FIG. 6A, eight thermoelectric converters 12 arranged along an axis (X-axis) of cylindrical body 11 are connected in series by feeder cables 21. In other words, eight thermoelectric converters 12 included in one structure C1 illustrated in FIG. 3B are connected in series. Six sets of eight thermoelectric converters 12 connected in series are arranged along the periphery of the cylindrical body 11. Driver 31 applies voltages individually to six sets of thermoelectric converters 12 connected in series. Voltages may be applied from driver 31 in parallel to six sets of thermoelectric converters 12. Driver 31 and feeder cables 21 are connected, for example, via a brush disposed on a rotary shaft of cylindrical body 11.

In the connecting state, currents respectively flowing through eight thermoelectric converters 12 arranged along the axis (X-axis) of cylindrical body 11 are identical. Therefore, driving of thermoelectric converters 12 cannot be controlled for each position along the axis (X-axis) of cylindrical body 11. Therefore, if heat pipe 17 is not mounted on heatsink 14, temperature gradient may arise along the axis (X-axis) in cylindrical body 11 as described below.

FIG. 6B is a graph schematically illustrating a cooling capacity when thermoelectric conversion unit 10 according to the comparative example is used.

In this comparative example, heat pipe 17 is not mounted on heatsink 14. In other words, in the comparative example, recess 14d and heat pipe 17 are omitted from the configuration illustrated in FIG. 3B, and thus the upper surface of heatsink 14 is a flat surface.

As illustrated in FIG. 6A, when cooling air is introduced from an opening (inlet port) at the X-axis positive side of cylindrical body 11, cooling air absorbs heat from fins 14a during passage through the interior of cylindrical body 11. Therefore, temperature of cooling air rises as the position along the axis shifts in the X axis negative direction as indicated by plots of black circles in FIG. 6B. When the temperature of cooling air rises, the heat quantity transferring from fins 14a to cooling air decreases. Therefore, in the comparative example, the temperature of heatsink 14 rises as it goes to the downstream side of the flow of cooling air. Consequently, the temperature of the heat dissipating surface of thermoelectric converter 12 (the lower surface of second substrate 12b illustrated in FIG. 5B) rises, and the cooling capacity of thermoelectric converter 12 is lowered as it goes to the downstream side of the flow of cooling air. With the phenomenon as described above, in the comparative example, the cooling capacities of thermoelectric converters 12 arranged along the axis of the X-axis are not uniform as indicated by plots of black rhombus in FIG. 6B.

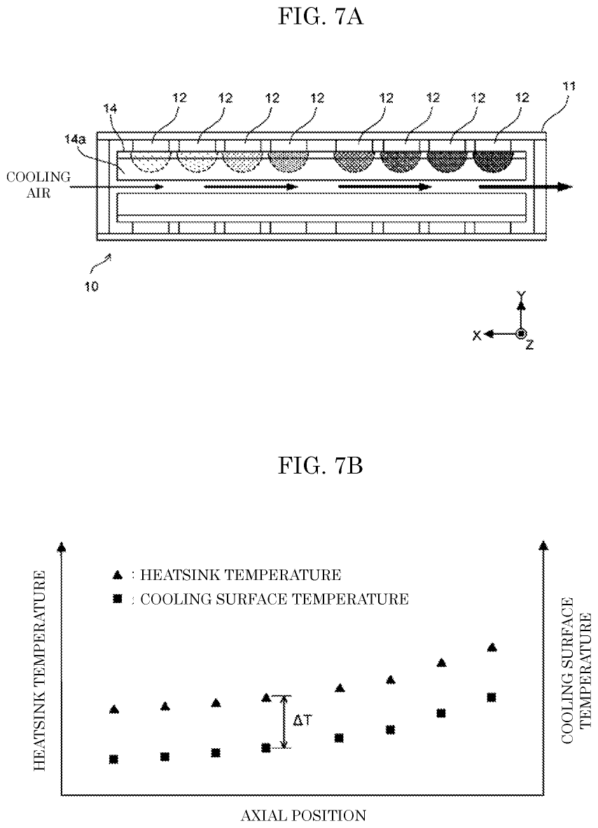

FIG. 7A is a view schematically illustrating a temperature distribution in heatsink 14 when thermoelectric conversion unit 10 according to the comparative example is used. For convenience, FIG. 7A illustrates the temperature of heatsink 14 by densities of hatching. Here, the higher the density of hatching, the more the temperature of heatsink 14 rises.

As described above, the more downstream cooling air flowing in the interior of cylindrical body 11 goes, the more the temperature rises. Therefore, the temperature of heatsink 14 at positions directly below respective thermoelectric converters 12 increases as it goes downstream of the flow of cooling air. Therefore, the temperatures of the heat dissipating surfaces of eight thermoelectric converters 12 arranged along the X-axis are higher as it goes downstream of cooling air. Consequently, the temperatures of the cooling surfaces (operating surfaces) of eight thermoelectric converters 12 arranged along the X-axis are higher as it goes downstream of cooling air.

FIG. 7B is a graph illustrating a relationship between a temperature of heatsink 14 at positions where thermoelectric converters 12 are disposed, and a temperature of cooling surfaces (operating surfaces) of respective thermoelectric converters 12 when thermoelectric conversion unit 10 according to the comparative example is used.

Thermoelectric converter 12 has a property that temperature difference ΔT between the temperature of the cooling surface (operating surface) and the temperature of the heat dissipating surface (inversely operating surface positioned at a side opposite to the operating surface) is constant. In contrast, in the comparative example, as described above, the temperatures of heatsink 14 (the temperature of the heat dissipating surface) at the positions directly below eight thermoelectric converters 12 arranged along the X-axis vary as indicated by plots of black triangles in FIG. 7B. Therefore, in the comparative example, the temperatures of cooling surfaces (operating surfaces) of eight thermoelectric converters 12 arranged along the X-axis vary as plots of black squares in FIG. 7B.

In this manner, in thermoelectric conversion unit 10 of the comparative example, the temperatures of the cooling surfaces (operating surfaces) of eight thermoelectric converters 12 arranged along the axis (X-axis) of cylindrical body 11 are not uniform. And thus temperature gradient occurs in the same tendency as the graph of black squares in FIG. 7B also in cylindrical body 11. Therefore, temperature gradient occurs in cylindrical body 11. Therefore, temperature gradient occurs in a width direction (X-axis direction) in printing paper P1 that contacts with cylindrical body 11. The temperature gradient of printing paper P1 may impair printing in back side printing unit 5 illustrated in FIG. 1.

In contrast, since heat pipe 17 is mounted on heatsink 14 in the present exemplary embodiment, even when the temperature difference arises in cooling air flowing in cylindrical body 11 as described above, the temperature of heatsink 14 is substantially uniformized in the longitudinal direction of heatsink 14 due to a high thermal conductive property of heat pipe 17.

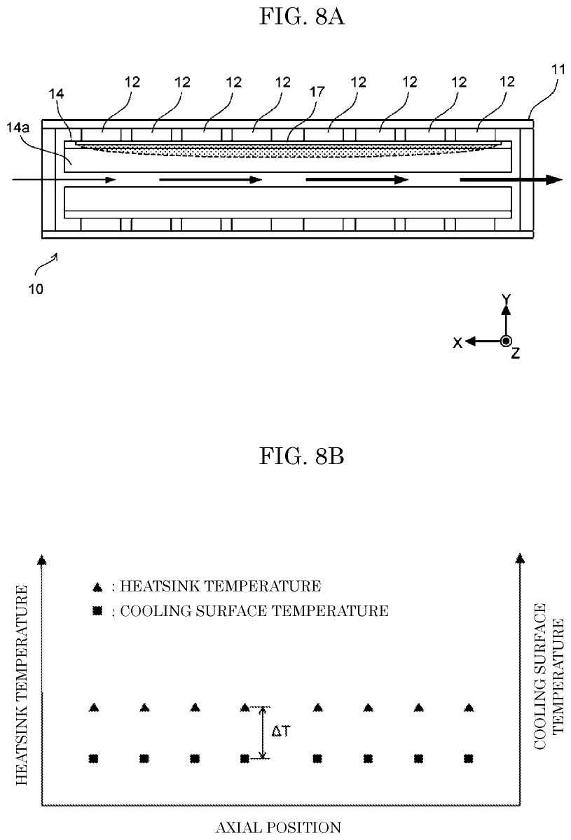

FIG. 8A is a view schematically illustrating a temperature distribution in heatsink 14 when thermoelectric conversion unit 10 according to the exemplary embodiment is used. FIG. 8A illustrates the temperature of heatsink 14 by hatching as in the same manner as in FIG. 7A.

As illustrated in FIG. 8A, in thermoelectric conversion unit 10 according to the exemplary embodiment, even when the temperature difference arises in cooling air flowing in cylindrical body 11, the temperature of heatsink 14 is substantially uniformized in the longitudinal direction. It may be assumed to be because the following operations are achieved by heat pipe 17.

In other words, on the downstream side, where the temperature is high, operating fluid 17b is gasified and draws heat from heatsink 14, so that the temperature of heatsink 14 is lowered. In contrast, on the upstream side, where the temperature is low, operating fluid 17b is liquidized and transfers heat to heatsink 14, so that the temperature of heatsink 14 rises. At this time, the larger the difference in temperature from an intermediate temperature at a position near the center of heatsink 14 in the longitudinal direction, the more significantly the temperatures at the respective positions of heatsink 14 lower and rise. By repeated operations as described above for a short time, the temperature distribution of heatsink 14 is uniformized to the intermediate temperature at the position near the center in the longitudinal direction.

It should be noted that, in a configuration in which heat pipe 17 is disposed on heatsink 14 in the same manner as the exemplary embodiment, the inventors of the present application measured the temperature of heatsink 14 at positions where respective thermoelectric converters 12 were located in a state in which thermoelectric converters 12 were driven. As a result, it was found that the temperatures of heatsink 14 at the positions where thermoelectric converters 12 were disposed were substantially uniformized by disposing heat pipe 17 on heatsink 14.

FIG. 8B is a graph illustrating a relationship between the temperature of heatsink 14 at positions where thermoelectric converters 12 are disposed, and the temperatures of cooling surfaces (operating surfaces) of respective thermoelectric converters 12 when thermoelectric conversion unit 10 according to the exemplary embodiment is used.

In thermoelectric conversion unit 10 according to the exemplary embodiment, the temperature distribution of heatsink 14 is substantially uniformized in the longitudinal direction of heatsink 14 by the operation of heat pipe 17 described above as the plots of black triangles in FIG. 8B. Therefore, the temperatures of cooling surfaces (operating surfaces) of eight thermoelectric converters 12 arranged along the X-axis are also substantially uniformized in the longitudinal direction of heatsink 14 so that the temperature difference from the temperature of heatsink 14 becomes ΔT. Therefore, in thermoelectric conversion unit 10 according to the exemplary embodiment, the temperatures of the cooling surfaces (operating surfaces) of eight thermoelectric converters 12 arranged along the X-axis are substantially the same as indicated by plots of black squares in FIG. 8B.

In this manner, in thermoelectric conversion unit 10 of the exemplary embodiment, the temperatures of the cooling surfaces (operating surfaces) of eight thermoelectric converters 12 arranged along the axis (X-axis) of cylindrical body 11 are substantially uniform, and cylindrical body 11 is also maintained at the substantially uniform temperature without causing substantial temperature gradient along the axis of cylindrical body 11. Therefore, printing paper P1 that contacts with cylindrical body 11 can be cooled substantially uniformly, and thus printing by back side printing unit 5 illustrated in FIG. 1 is adequately achieved.

### Effects of Exemplary Embodiment

As stated above, the present exemplary embodiment exerts the following effects.

The temperatures of heatsink 14 at positions where the plurality of thermoelectric converters 12 are disposed may be maintained to be substantially equal by the operation of heat pipe 17. Accordingly, the temperature of surfaces (heat dissipating surfaces) of the plurality of thermoelectric converters 12 positioned at a side opposite to the operating surfaces (cooling surfaces) can be maintained substantially uniform.

Accordingly, the operating surface (cooling surfaces) of the plurality of thermoelectric converters 12 may be maintained more stably at a uniform temperature.

Eight thermoelectric converters 12 are arranged in a row along the axis of cylindrical body 11, and heat pipe 17 is mounted on heatsink 14 so as to linearly coupling portions where thermoelectric converters 12 at both ends of the row are disposed. Accordingly, heat pipe 17 having a linear shape can be smoothly disposed on heatsink 14, and simultaneously, the temperatures of surfaces (heat dissipating surfaces) of eight thermoelectric converters 12 mounted linearly on heatsink 14 positioned at a side opposite to the operating surfaces (cooling surfaces) can be maintained substantially uniformly.

Six sets of eight thermoelectric converters 12 arranged in a row are disposed on an inner peripheral surface of cylindrical body 11 along a periphery of cylindrical body 11 at constant intervals, and heatsink 14 and heat pipe 17 are provided for each of the sets of thermoelectric converters 12 on each row.

Accordingly, the outer peripheral surface of cylindrical body 11 can efficiently be maintained at a substantially uniform cooling temperature.

Six heatsinks 14 mounted on the inner peripheral surface of cylindrical body 11 are each provided with fins 14a extending toward a central axis of cylindrical body 11. Accordingly, heat transferred from thermoelectric converters 12 to respective heatsinks 14 is efficiently exhausted by flowing cooling air in the interior of cylindrical body 11.

### First Modified Example

The exemplary embodiment of the present disclosure has been described. The scope of the present disclosure, however, should not be limited to the exemplary embodiment.

For example, in the exemplary embodiment descried above, eight thermoelectric converters 12 arranged along the axis of cylindrical body 11 are connected in series as illustrated in FIG. 6A. However, a connecting state in which six thermoelectric converters 12 arranged along a periphery of cylindrical body 11 are connected in series is also applicable.

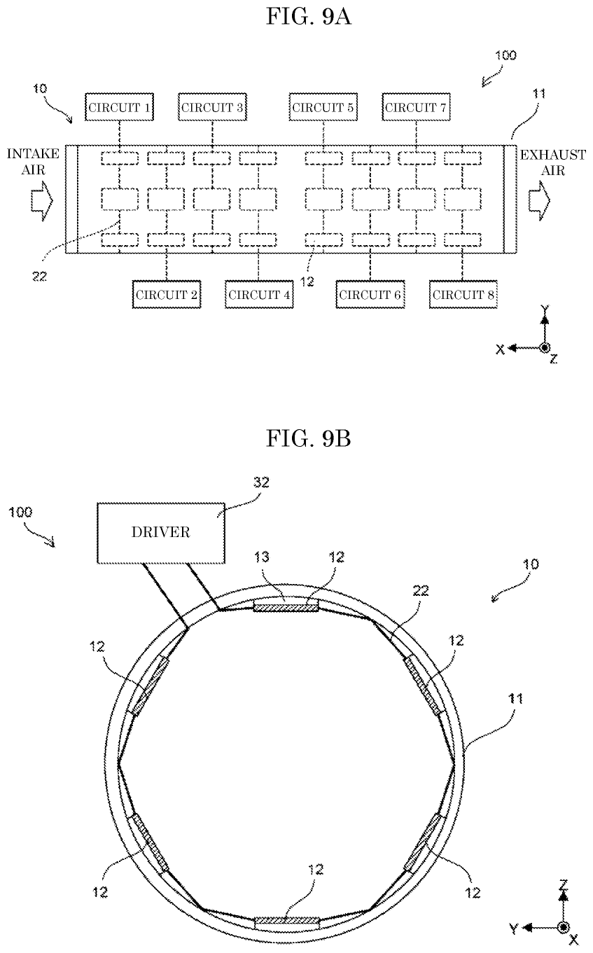

FIGS. 9A and 9B are views schematically illustrating a connecting state of feeder cables 22 in thermoelectric conversion unit 10 according to a first modified example. FIG. 9A is a view of thermoelectric conversion unit 10 as seen from a Z-axis positive side, and FIG. 9B is a view of thermoelectric conversion unit 10 as seen from the X-axis positive side. For convenience, illustration of a configuration of cylindrical body 11 on the central axis side with respect to thermoelectric converters 12 is omitted in FIG. 9B.

As illustrated in FIGS. 9A and 9B, in this modified example, six thermoelectric converters 12 arranged along a periphery (around X-axis) of cylindrical body 11 are connected in series by feeder cables 22. In other words, six thermoelectric converters 12 arranged along a periphery (around X-axis) of cylindrical body 11 are connected in series to form one circuit. Eight circuits including six thermoelectric converters 12 connected in series are formed along the axis (X-axis) of cylindrical body 11. Driver 32 applies voltages to the respective circuits individually. Driver 32 and feeder cables 22 are connected, for example, via a brush disposed on a rotary shaft of cylindrical body 11.

Driver 32 and thermoelectric conversion unit 10 (including feeder cables 22) in this modified example constitute thermoelectric conversion device 100.

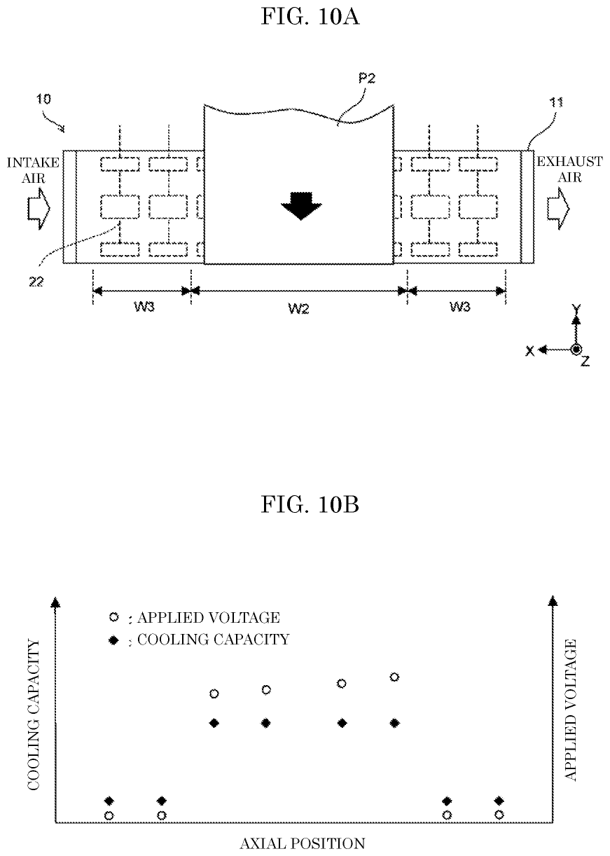

In the connecting state of this modified example, in a case where printing paper P2 having a smaller width than that of printing paper P1 is supplied to thermoelectric conversion unit 10 as illustrated in FIG. 10A, an occurrence of wasted power consumption in thermoelectric converters 12 is suppressed.

In other words, when printing paper P2 having small width is supplied to thermoelectric conversion unit 10, printing paper P2 does not contact with regions W3 on both sides of printing paper P2. In contrast, in the connecting state of the exemplary embodiment described above, eight thermoelectric converters 12 arranged along the axis (X-axis) are connected in series. Thus a current also flows through thermoelectric converters 12 included in regions W3 (non-contact regions) in the same manner as thermoelectric converter 12 at a center to apply a cooling effect to cylindrical body 11. Therefore, wasted power is consumed by cooling of regions W3. Cylindrical body 11 is excessively cooled in regions W3 (non-contact regions).

In contrast, in this modified example, six thermoelectric converters 12 arranged along a periphery of cylindrical body 11 are connected in series by feeder cables 22. Therefore, by controlling power feeding to thermoelectric converters 12 included in regions W3 (non-contact regions), these problems may be solved.

In other words, as illustrated in FIG. 10B, the voltage to be applied to thermoelectric converters 12 included in regions W3 is lowered compared with the voltage applied to thermoelectric converters 12 included in a central region where printing paper P2 contacts. For example, driver 32 stops application of voltage to thermoelectric converters 12 included in regions W3 (applied voltage=0). Alternatively, driver 32 lowers voltages to be applied to thermoelectric converters 12 included in regions W3 to voltages near zero. Accordingly, excessive cooling of thermoelectric conversion unit 10 in regions W3 is suppressed, and thus wasted power consumption in regions W3 may be avoided.

It should be noted that, in this modified example, heat pipe 17 is mounted on heatsink 14 so as to face the heat dissipating surfaces of thermoelectric converters 12, as the same as the above exemplary embodiment. If heat pipe 17 is disposed so as to face the cooling surfaces of thermoelectric converters 12 instead of the heat dissipating surfaces, regions W3 of cylindrical body 11 is cooled even when the voltage to be applied to eight thermoelectric converters 12 arranged along the X-axis is controlled as illustrated in FIG. 10B. For example, in the case where heat pipe 17 is disposed on the cooling surfaces of these eight thermoelectric converters 12 so as to connect presser plates 13 (see FIG. 3B), which press upper surfaces of eight thermoelectric converters 12 arranged on heatsink 14, even when the voltage to be applied to thermoelectric converters 12 included in regions W3 in FIG. 10A is blocked, heat of cylindrical body 11 in the range of regions W3 transfers to thermoelectric converters 12 in region W2 via heat pipe 17, so that cylindrical body 11 is cooled in the range of regions W3.

In this modified example, heat of cylindrical body 11 in the range of regions W3 does not transfer to thermoelectric converters 12 in region W2 via heat pipe 17 because heat pipe 17 is mounted on heatsink 14 in the same manner as the exemplary embodiment descried above. Therefore, according to this modified example, excessive cooling of cylindrical body 11 in regions W3 may be suppressed by controlling the voltages to be applied to eight thermoelectric converters 12 arranged along the X-axis as illustrated in FIG. 10B.

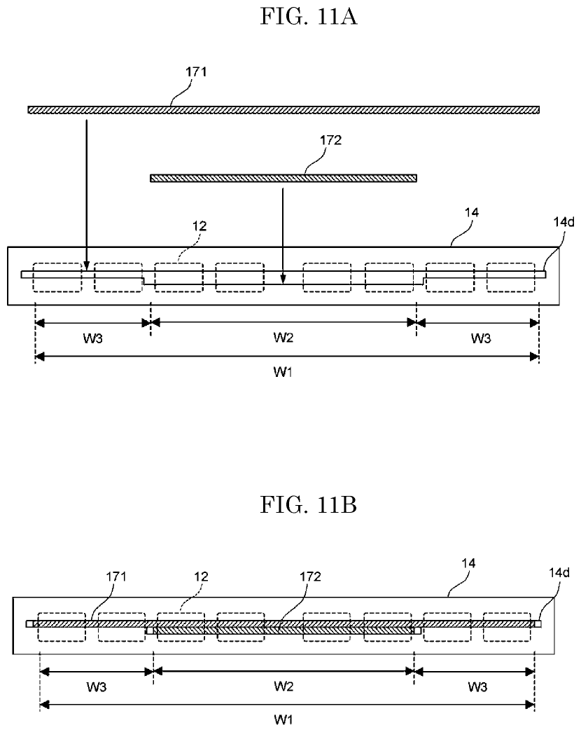

It should be noted that, in this modified example, heat pipes 171, 172 having two different lengths corresponding respectively to region W1 and region W2 may be mounted on heatsink 14 as illustrated in FIGS. 11A and 11B. FIG. 11A is a view illustrating a state in which heat pipes 171, 172 are not fitted in recess 14d viewed from an upper surface side of heatsink 14, and FIG. 11B is a view illustrating a state in which heat pipes 171, 172 are fitted into recess 14d viewed form the upper surface side of heatsink 14. Here, the shape of recess 14d in plan view is modified to a shape corresponding to the lengths of two heat pipes 171, 172.

In this modified example, when printing paper P1 having a wider width is supplied, all of thermoelectric converters 12 included in region W1 are driven.

In this case, heat pipe 171, which is longer, acts effectively on uniformization of the temperature of heatsink 14 in region W1. Also, when printing paper P2 having a narrow width is supplied, four thermoelectric converters 12 included in region W2 are driven. In this case, mainly heat pipe 172 having a short length acts effectively on uniformization of the temperature of heatsink 14 in region W2. Accordingly, printing paper P1, P2 are cooled efficiently and stably irrespective of which of printing papers P1, P2 is supplied to thermoelectric conversion unit 10.

### Second Modified Example

In the exemplary embodiment described above, heat pipe 17 is configured to be fit into recess 14d provided on an upper surface of heatsink 14. However, the method of mounting heat pipe 17 to heatsink 14 is not limited thereto.

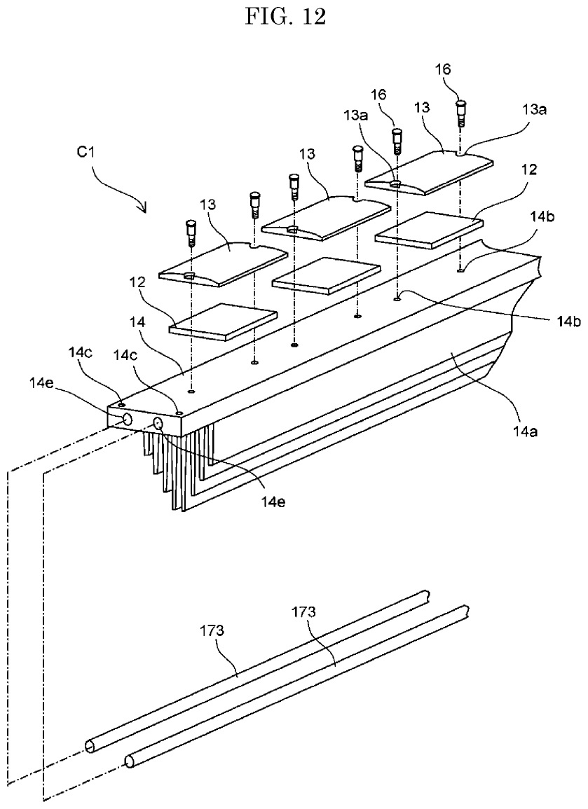

For example, as illustrated in FIG. 12, heat pipe 173 may be installed in heatsink 14 by inserting heat pipe 173 into holes 14e formed to penetrate through heatsink 14 in the longitudinal direction. In this case, holes 14e do not necessarily have to be penetrated. For example, one of ends of holes 14e reaches to a side surface of heatsink 14, and the other end terminates in the interior of heatsink 14. Also, the number of holes 14e is not limited to two, and other number of holes 14e may be provided. In addition, as the same manner of two heat pipes 171, 172 illustrated in FIGS. 11A and 11B, two heat pipes 173 may have different lengths from each other. Presser plates 13 are each provided with two holes 13a, and the upper surface of heatsink 14 is provided with screw holes 14b at positions corresponding to two holes 13a of each of presser plates 13.

It should be noted that, in this modified example, the cross-sectional shape of each of heat pipes 173 is a circular shape unlike the exemplary embodiment described above. Heat pipe 171 has higher thermal conductivity when it has a cylindrical shape as compared with a case of having a square column shape. Therefore, even when heat pipes 173 are disposed in the interior of heatsink 14 and are located farther from thermoelectric converters 12 as in this modified example, the temperature of heatsink 14 can be effectively uniformized by using heat pipes 173 having a cylindrical shape.

### Other Modified Example

In the exemplary embodiment described above, the case where thermoelectric conversion device 100 is used as cooling device for cooling cooling printing papers P1, P2, which are objects, has been described. However, for example, thermoelectric conversion device 100 may also be used as a heating device by exchanging polarities of voltage feed terminals of driver 32 in FIG. 6A. In this case, the operating surfaces of thermoelectric converters 12 serve as heating surfaces, and inversely operating surfaces serve as heat absorbing surfaces.

It should be noted that when printer 1 is used in district of cold weather, the temperature of thermoelectric conversion unit 10 may not reach a predetermined temperature when the power of printer 1 is turned ON. In such a case, by inverting the polarities of voltage to be applied to thermoelectric conversion unit 10, the temperature of cylindrical body 11 may be adjusted rapidly to a temperature close to the proper temperature. Consequently, time needed until the start of printing after the power of printer 1 is turned ON may be reduced.

In addition, thermoelectric conversion device 100 does not necessarily have to be provided on printer 1. Thermoelectric conversion device 100 may be used in other apparatuses which require cooling or heating. Also, the shape of cylindrical body 11 when seen in the X-axis direction does not necessarily have to be circular, and may be modified to, for example, a rounded square as needed depending on demand on the apparatus side in which thermoelectric conversion device 100 is used.

In addition, thermoelectric converters 12 do not necessarily have to be mounted on the inner peripheral surface of cylindrical body 11, and may be mounted on, for example, the outer peripheral surface of cylindrical body 11, which may be changed as needed depending on the demand on the apparatus side in which thermoelectric conversion device 100 is used. Also, arrangement layout of thermoelectric converters 12 or the number of thermoelectric converters 12 to be disposed may also be changed as needed. In the same manner, the number of arrangement or the position of arrangement of heat pipe 17 in heatsink 14 may be changed as appropriate.

In addition, a mounting structure of thermoelectric converters 12 with respect to cylindrical body 11 is not limited to the mounting structure illustrated in FIGS. 3A and 3B, and may be changed variously. For example, in the exemplary embodiment, one heatsink 14 is allocated to eight thermoelectric converters 12 arranged along the axis of cylindrical body 11. However, heatsinks 14 may be allocated individually for eight thermoelectric converters 12 arranged along the axis of cylindrical body 11, or one heatsink 14 may be allocated to two adjacent thermoelectric converters 12 among eight thermoelectric converters 12. In such a case as well, respective heatsinks arranged along the axis of cylindrical body 11 are coupled by heat pipe 17 so as to allow transmission of heat with each other.

In addition, the cooling object may also be changed to paper, cloth, or the like used for printing, or may be changed variously. The thermoelectric conversion device may not use cylindrical body 11.

The exemplary embodiment of the present disclosure can be modified in various manners as appropriate within the scope of the technical idea recited in the claims.

### REFERENCE MARKS IN THE DRAWINGS

1: printer
10: thermoelectric conversion unit
11: cylindrical body
12: thermoelectric converter
14: heatsink (heat transfer member)
14a: fin
17: heat pipe
171, 172, 173: heat pipe
100: thermoelectric conversion device

1. A thermoelectric conversion device comprising:
a cylindrical body made of a thermally conductive material;
a plurality of thermoelectric converters disposed on an inner peripheral surface of the cylindrical body, each of the plurality of thermoelectric converters having an operating surface facing the inner peripheral surface and an inversely operating surface positioned at a side opposite to the operating surface;
a heat transfer member disposed on the inversely operating surface; and
a heat pipe installed in the heat transfer member, wherein:
heat transfers between each of the plurality of thermoelectric converters and the heat transfer member via the inversely operating surface,
the plurality of thermoelectric converters are divided into a plurality of sets of the thermoelectric converters,
the heat transfer member and the heat pipe are provided for each of the plurality of sets of the thermoelectric converters, and
the heat pipe is disposed, in the heat transfer member, along positions of respective thermoelectric converters included in each of the plurality of sets of the thermoelectric converters.

2. The thermoelectric conversion device according to claim 1, wherein:
the thermoelectric converters included in the each of the plurality of sets of the thermoelectric converters are arranged to align in a linear row extending parallel with a central axis of the cylindrical body, and
the heat pipe is disposed, in the heat transfer member, to linearly connect between positions of respective two thermoelectric converters disposed at both ends of the liner row.

3. The thermoelectric conversion device according to claim 1, wherein the plurality of sets of the thermoelectric converters are disposed along a periphery of the cylindrical body at predetermined intervals.

4. The thermoelectric conversion device according to claim 1, wherein the heat transfer member includes a fin extending toward the central axis of the cylindrical body.

5. The thermoelectric conversion device according to claim 1, wherein each of the plurality of thermoelectric converters is controlled to cool an object that is to be in contact with an outer peripheral surface of the cylindrical body.

6. The thermoelectric conversion device according to claim 1, wherein:
the heat transfer member has a recess on a surface of the heat transfer member, the surface facing the inversely operating surface, and
the heat pipe is fitted into the recess.

7. The thermoelectric conversion device according to claim 6, wherein at least a part of the heat pipe is positioned in a space defined by the recess and the inversely operating surface.

8. The thermoelectric conversion device according to claim 1, wherein the heat pipe is in contact with the inversely operating surface.

9. A printer comprising:
the thermoelectric conversion device according to claim 1,
a printing section configured to perform printing on a sheet-shaped material to be printed; and
a conveying section configured to convey the sheet-shaped material from the printing section to the thermoelectric conversion device.

10. The printer according to claim 9, wherein:
the printing section is configured to perform printing on a plurality of the sheet-shaped materials having different widths from each other, and
the thermoelectric conversion device includes a plurality of heat pipes including the heat pipe, the plurality of heat pipes having different lengths respectively corresponding to the different widths of the plurality of the sheet-shaped materials.
